(19) United States
(12) Patent Application Publication
(10) Pub. No.: US 2012/0199837 A1
(43) Pub. Date: Aug. 9, 2012

(54) ORGANIC ELECTROLUMINESCENT ELEMENT AND ORGANIC ELECTROLUMINESCENT DISPLAY DEVICE

(75) Inventors: Yuhki Kobayashi, Osaka (JP); Yoshimasa Fujita, Osaka (JP)

(73) Assignee: Sharp Kabushiki Kaisha, Osaka (JP)

(21) Appl. No.: 13/500,058

(22) PCT Filed: Oct. 4, 2010
(86) PCT No.: PCT/JP2010/067385

§ 371 Date: Apr. 3, 2012

(30) Foreign Application Priority Data
Oct. 6, 2009 (JP) 2009-232661

(51) Int. Cl. H01L 51/52

(52) U.S. Cl. 257/59; 257/99; 257/72; 257/E51.018

(57) ABSTRACT

In an organic EL element (7), a positive and negative charge transporting layer (30) includes an anode (4), an organic EL layer (8), and a cathode (9). The anode (4) is constituted by an acceptor and the cathode (9) is constituted by a donor. An acceptor that is the same as the material of the anode (4) is added to the hole transport region (100) in the organic EL layer (8) so that a concentration of the acceptor becomes continuously lower toward the light-emitting region (101). A donor that is the same as the material of the cathode (9) is added to the electron transport region (102) so that a concentration of the donor becomes continuously lower toward the light-emitting region (101).

### TECHNICAL FIELD

The present invention relates to an organic electroluminescent element that achieves high luminance, high efficiency, and long lifespan with a simple structure, and an organic electroluminescent display device.

### BACKGROUND ART

In recent years, there has been a growing need for flat-panel displays (FPD) in place of CRT-based display devices, which were conventionally the mainstream of display devices. There are many different types of FPDs, and known examples of FPDs include non-self-light-emitting liquid crystal displays (LCD), self-light-emitting plasma display panels (PDP), inorganic electroluminescent (inorganic EL) displays, and organic electroluminescent (organic EL) displays.

Among these FPDs, research and development of organic EL displays is particularly popular because an element (organic EL element) used for display in an organic EL display (i) is thin and light-weight and (ii) has characteristics such as low voltage driving, high luminance, and self-light emission. Recently, application of the organic EL element to (i) a light source of an electrophotographic copier, a printer, and the like, (ii) light emission, or the like is anticipated. Use of the organic EL element for light emission is advantageous in that the organic EL element (i) is a surface emitting element, (ii) has high color rendering properties, and allows easy light control. In comparison with a fluorescent light, the organic EL element has many advantages: (i) the fluorescent light contains mercury whereas the organic EL element contains no mercury, (ii) light emitted from the organic EL element does not include ultraviolet ray, and (iii) so on.

In general, an organic EL element has a heterojunction structure as illustrated in FIG. 7. FIG. 7 is a cross-sectional view illustrating a conventional heterojunction-type organic EL element 20a. The heterojunction-type organic EL element 20a illustrated in FIG. 7 has a multilayer structure constituted by (i) an anode 12 and a cathode 19 and (ii) a hole injection layer 13, a hole transport layer 14, a light-emitting layer 15, a hole blocking layer 16, an electron transport layer 17, an electron injection layer 18, and the like, which are provided between the anode 12 and the cathode 19. By employing such a multi-layer structure, it is possible to achieve both an improvement in luminous efficiency and a longer light emission lifetime.

In recent years, an organic EL element employing a phosphorescent material as a light-emitting layer is coming into wider use. The organic EL element employing phosphorescent material has advantages such as high luminous efficiency and long light emission lifetime.

Although an organic EL element having a configuration as described above can achieve improvement in luminous efficiency and light emission lifetime, complexity in the layer structure of such an organic EL element undesirably leads to a complication of a fabrication process. Moreover, the complication of the fabrication process gives rise to problems such as an increase in cost of a fabricating apparatus and of a material.

To solve the foregoing problems, a homojunction-type organic EL element 20b as illustrated in FIG. 8 has been developed. FIG. 8 is a cross-sectional view illustrating the conventional homojunction-type organic EL element 20b. In the homojunction-type organic EL element 20b illustrated in FIG. 8, an acceptor region 200, a light-emitting region 201, a donor region 202, and the like are formed by adding other substances into a matrix (host) made from a single substance. The acceptor region 200, the light-emitting region 201, the donor region 202, and the like as a whole constitute a positive and negative charge transporting light-emitting layer. That is, the homojunction-type organic EL element has a plurality of regions within a single matrix (positive and negative charge transporting light-emitting layer). Such a configuration, which is simple in terms of layer configuration, allows the fabrication process to be simplified.

For example, Non-patent Literature 1 discloses a homojunction-type organic EL element emitting three primary colors of light. In the organic EL element disclosed in Non-patent Literature 1, an organic thin-film with a thickness of 50 nm to 100 nm and an Al metal (cathode) are formed in this order on an ITO transparent electrode (anode) by vapor deposition. The organic thin-film contains bis(carbazolyl)benzodifuran (CZBDF) as a single matrix (host). An inorganic oxidant (vanadium pentoxide), which serves as a p-type dopant, and CZBDF are applied onto the anode by co-evaporation so as to have a thickness of 30 nm in the matrix. A reducing agent (metal cesium), which serves as an n-type dopant, and CZBDF are applied onto the cathode by co-evaporation so as to have a thickness of 20 nm in the matrix. This configuration facilitates injection and transport of an electrode to the CZBDF.

In the organic EL element of Non-patent Literature 1, a blue florescent pigment, a green florescent pigment, or a red phosphorescent pigment is added to a middle layer (50 nm to 100 nm in thickness), to which neither the oxidant nor the reducing agent is added. This realizes emission of three primary colors of light by means of the blue, green, and red pigments. In particular, a green fluorescent element exhibits an external quantum efficiency of 4.2%, which is almost as high as theoretical limitation of efficiency of a fluorescent organic EL element (5%), with a luminance as high as 60,000 cd/m².

The foregoing characteristics are attributable to the following characteristics (1) through (3) of CZBDF. That is, CZBDF (1) is highly balanced, highly mobile, and bipolar, (2) is a wide gap material with a sufficiently large energy gap between a Highest Occupied Molecular Orbital (HOMO) and a Lowest Unoccupied Molecular Orbital (LUMO) (about 3 eV), and (3) allows an electric charge to be efficiently confined in a light-emitting pigment.

### CITATION LIST

### Non-Patent Literature

Non-patent Literature 1
Advanced Materials 2009, Vol. 21, No. 37, pp. 3776-3779

### SUMMARY OF INVENTION

### Technical Problem

However, in the homojunction-type organic EL element, (i) a region to which a p-type dopant is added in high concentration is in direct contact with a region to which an organic light-emitting material is added and (ii) a region to which an n-type dopant is added in high concentration is in direct contact with the region to which the organic light-emitting material is added. As such, it is impossible to transport efficiently a hole, via the p-type dopant, to a positive and negative charge transporting material in the region to which the organic light-emitting material is added. Likewise, it is impossible to transport efficiently an electron, via the n-type dopant, to the positive and negative charge transporting material in the region to which the organic light-emitting material is added. In addition, the following problem still remains unsolved. That is, an energy barrier is present between (i) each of the regions to which the respective dopants are added in high concentration and (ii) a corresponding one of the electrodes. This prevents a carrier from being properly injected from the corresponding one of the electrodes into the positive and negative charge transporting material. Because of this, the organic EL element still has the problem of poor characteristics in driving voltage, luminous efficiency, lifespan, and the like.

The anode and an organic layer are provided as different layers. Likewise, the cathode and the organic layer are provided as different layers. Because of this, the problem of an increase in cost, caused by the complicated layer structure of the organic EL element, still remains unsolved.

The present invention is accomplished in view of the foregoing problems. An object of the present invention is to provide an organic EL element that (i) has a simple layer structure, (ii) has a high performance (low voltage driving, high luminous efficiency, and long lifespan), and (iii) low cost, and an organic EL display including the organic EL element.

### Solution to Problem

In order to attain the object, an organic electroluminescent element in accordance with the present invention includes: a substrate; a pair of electrodes; and an organic layer, sandwiched between the pair of electrodes, which includes at least a light-emitting region to which an organic light-emitting material is added, at least one of the pair of electrodes being constituted by a dopant which enhances transportation of a carrier to be injected into the organic layer via the at least one of the pair of electrodes, the organic layer further including a carrier transport region to which the dopant is added so that the dopant has such a concentration gradient in which a concentration of the dopant changes continuously from the at least one of the electrodes toward the light-emitting region.

According to the configuration, in the organic electroluminescent (organic EL) element in accordance with the present invention, the at least one of the pair of electrodes (anode and cathode) which sandwich the organic layer therebetween is constituted by the dopant enhancing the carrier, which has been injected from the electrode, in the organic layer. For example, the anode is constituted by an acceptor or the cathode is constituted by a donor.

In a case where the anode is constituted by the acceptor, the acceptor is added to the carrier transport region (hole transport region) so that the concentration of the acceptor becomes lower toward the light-emitting region. As such, in a boundary region between the anode and the hole transport region, a work function level of the anode substantially matches a Highest Occupied Molecular Orbital (HOMO) on which a hole propagates through the acceptor. This causes no energy barrier to be generated in the boundary region between the anode and the hole transport region and, ultimately, allows a hole to propagate efficiently from the anode to the hole transport region. In a boundary region between the light-emitting region and the hole transport region, a level of a host material contained in the hole transport region substantially matches a HOMO on which a hole propagates through the acceptor. This allows a hole to propagate efficiently from the hole transport region to the light-emitting region.

In contrast, in a case where the cathode is constituted by the donor, the donor is added to the carrier transport region (electron transport region) so that the concentration of the donor becomes lower toward the light-emitting region. As such, in a boundary region between the cathode and the electron transport region, a work function level of the cathode substantially matches a Lowest Unoccupied Molecular Orbital (LUMO) on which an electron propagates through the donor. This causes no energy barrier to be generated in the boundary region between the cathode and the electron transport region and, ultimately, allows an electron to propagate efficiently from the cathode to the electron transport region. In a boundary region between the light-emitting region and the electron transport region, a LUMO level of a host material contained in the electron transport region substantially matches a LUMO on which an electron propagates through the donor. This allows an electron to propagate efficiently from the electron transport region to the light-emitting region.

Thus, in the organic EL element in accordance with the present invention, it is possible to inject and transport efficiently at least one of a hole or an electron. This allows the organic EL element to have an improved luminous efficiency, a longer lifespan, and a lower driving voltage. Further, it becomes possible to form at least one of the anode and the cathode so that the at least one of the anode and the cathode and the organic layer constitute a single layer, not different layers.

As described above, in the organic EL element in accordance with the present invention, the organic EL element has a simple layer structure. This allows a significant increase in cost for fabricating the organic EL element.

In order to attain the object, an organic electroluminescent display device in accordance with the present invention includes a light-emitting device as described above.

Since the foregoing configuration includes an organic electroluminescent element in which holes and electrons can be efficiently injected and transported into a region to which an organic light-emitting material is added, the foregoing configuration can provide a high-luminance, high-efficiency, and long-life display device.

Additional objects, features, and strengths of the present invention will be made clear by the description below. Further, the advantages of the present invention will be evident from the following explanation in reference to the drawings.

### Advantageous Effects of Invention

According to the organic EL element in accordance with the present invention, the organic EL element can have a simpler layer structure.

### BRIEF DESCRIPTION OF DRAWINGS

FIG. 1

FIG. 1 is a view (i) illustrating a cross-section of an organic electroluminescent element in accordance with an embodiment of the present invention and (ii) showing a concentration of each of materials constituting the organic electroluminescent element.

FIG. 2

FIG. 2 is a cross-sectional view illustrating an organic electroluminescent display device in accordance with an embodiment of the present invention.

FIG. 3

FIG. 3 is a cross-sectional view illustrating an organic electroluminescent display device in accordance with an embodiment of the present invention.

FIG. 4

FIG. 4 is a view (i) illustrating a cross-section of an organic electroluminescent element in accordance with an embodiment of the present invention and (ii) showing a concentration of each of materials constituting the organic electroluminescent element.

FIG. 5

FIG. 5 is a cross-sectional view illustrating an organic electroluminescent display device in accordance with an embodiment of the present invention.

FIG. 6

FIG. 6 is a view (i) illustrating a cross-section of an organic electroluminescent element in accordance with an embodiment of the present invention and (ii) showing a concentration of each of materials constituting the organic electroluminescent element.

FIG. 7

FIG. 7 is a cross-sectional view illustrating a conventional heterojunction-type organic electroluminescent element.

FIG. 8

FIG. 8 is a cross-sectional view illustrating a conventional homojunction-type organic electroluminescent element.

### DESCRIPTION OF EMBODIMENTS

### First Embodiment

### General configuration of Organic Electroluminescent Display Device 10

The following description will discuss, with reference to FIG. 2, a general configuration of an organic EL display device 10 in accordance with the present embodiment. FIG. 2 is a cross-sectional view illustrating the organic electroluminescent display device 10 (hereinafter referred to as an organic EL display device 10). As illustrated in FIG. 2, the organic EL display device 10 includes an insulating substrate 1, a plurality of thin-film transistors (TFTs) 2, interlayer insulating films 3, anodes 4 (electrodes), edge covers 5, organic EL layers 8 (organic layers), and cathodes 9 (electrodes).

On the insulating substrate 1, the plurality of TFTs 2 are provided at predetermined intervals. Each of the interlayer insulating films 3, which have been smoothed, is provided on corresponding two of the plurality of TFTs 2. A terminal of each of the plurality of TFTs 2 is electrically connected with a corresponding one of the anodes 4 via a corresponding contact hole provided in the interlayer insulating film 3. Each of the organic EL layers 8 and a corresponding one of the cathodes 9 are provided on a corresponding one of the anodes 4 in this order so as to face a corresponding one of the plurality of TFTs 2. The insulating substrate 1, an anode 4, an organic EL layer 8, and a cathode 9 constitute an organic EL element 7 (organic electroluminescent element). An edge cover 5 is provided between respective adjacent organic EL elements 7.

According to the present embodiment, the anode 4, the organic EL layer 8, and the cathode 9 constitute a positive and negative charge transporting layer 30 (a single layer) containing a positive and negative charge transporting material. This will be later described in detail. The organic EL layer 8 is provided between a pair of electrodes (an anode 4 and a cathode 9). In the present embodiment, one of the pair of electrodes is an anode and the other of the pair of electrodes is a cathode.

In the anode 4, an acceptor (dopant) is added to the positive and negative charge transporting material so as to have a concentration of 100% by weight. The acceptor is added to the positive and negative charge transporting material so that the concentration becomes lower from the anode 4 toward the cathode 9. In the cathode 9, a donor (dopant) is added to the positive and negative charge transporting material so as to have a concentration of 100% by weight. The donor is added to the positive and negative charge transporting material so that to the concentration becomes lower from the cathode 9 toward the anode 4. The positive and negative charge transporting material has a region to which an organic light-emitting material is added. Such a region is located between (i) a region in which the acceptor has a concentration gradient in which the concentration becomes continuously lower and (ii) a region in which the donor has a concentration gradient in which the concentration becomes continuously lower.

The configuration allows an efficient injection of a hole (carrier) from the anode 4 and an efficient injection of an electron (carrier) from the cathode 9. The configuration further allows a hole and an electron to efficiently move in the organic EL layer 8. This will be later described in detail.

### General Configuration of Insulating Substrate 1

As early described, the organic EL display device 10 includes the insulating substrate 1, the thin-film transistor (TFT) 2, the interlayer insulating film 3, the anode 4, the edge cover 5, the organic EL layer 8, and the cathode 9. The following description will discuss in detail each of these members.

First, the insulating substrate 1 will be described. Examples of the insulating substrate 1 encompass (i) an inorganic material substrate made from a material such as glass or quartz, (ii) a plastic substrate made from a material such as polyethylene terephthalate or a polyimide resin, (iii) a substrate obtained by coating a metal substrate made from a material such as aluminum (Al) or iron with an insulator made from a material such as silicon oxide or an organic insulating material, and (iv) a substrate obtained by subjecting a surface of a metal substrate made from a material such as Al to an insulating treatment by a method such as anodization.

Which of the substrates to actually employ as the insulating substrate 1 is determined taking into account a type of the TFT 2. For example, in a case of employing a TFT 2 made from polycrystalline silicon, it is preferable that the insulating substrate 1 be a substrate that neither melts nor distorts at a temperature of 500° C. or lower. This is because such a TFT 2 is formed in a low temperature process. In a case of employing a TFT 2 made from polycrystalline silicon, it is preferable that the insulating substrate 1 be a substrate that neither melts nor distorts at a temperature of 1,000° C. or lower. This is because such a TFT 2 is formed in a high temperature process.

Note that, in a case where light emitted from the organic EL layer 8 is emitted from an insulating substrate 1 side, it is necessary that the insulating substrate 1 be a transparent or translucent substrate.

### General Configuration of TFT 2

The following description will discuss the TFT 2. The TFT 2 functions as a switching device of the organic EL element 7. Examples of materials of the TFT 2 therefore encompass (i) inorganic semiconductor materials such as amorphous silicon, polycrystalline silicon, microcrystalline silicon, and cadmium selenide and (ii) organic semiconductor materials such as polythiophen derivatives and pentacene. It is possible to use a metal-insulator-metal (MIM) diode in place of the TFT 2.

### General Configuration of Interlayer Insulating Film 3

The interlayer insulating film 3 will be described below. Examples of materials of the interlayer insulating film 3 encompass (i) inorganic materials such as silicon oxide and silicon nitride and (ii) organic resin materials such as an acrylic resin, a polyimide resin, photosensitive sol-gel materials, and a novolak resin. Examples of acrylic resin encompass Optomer® series (product of JSR Corporation). Examples of polyimide resin encompass Photoneece™ series (product of Toray Co., Ltd.). Note that, in a case where the organic EL display device 10 is of a bottom emission type, an opaque material such as a polyimide resin is unsuitable. This is because it is necessary that the interlayer insulating film 3 have optical transparency.

### Configuration of Anode 4, Organic EL layer 8, and Cathode 9

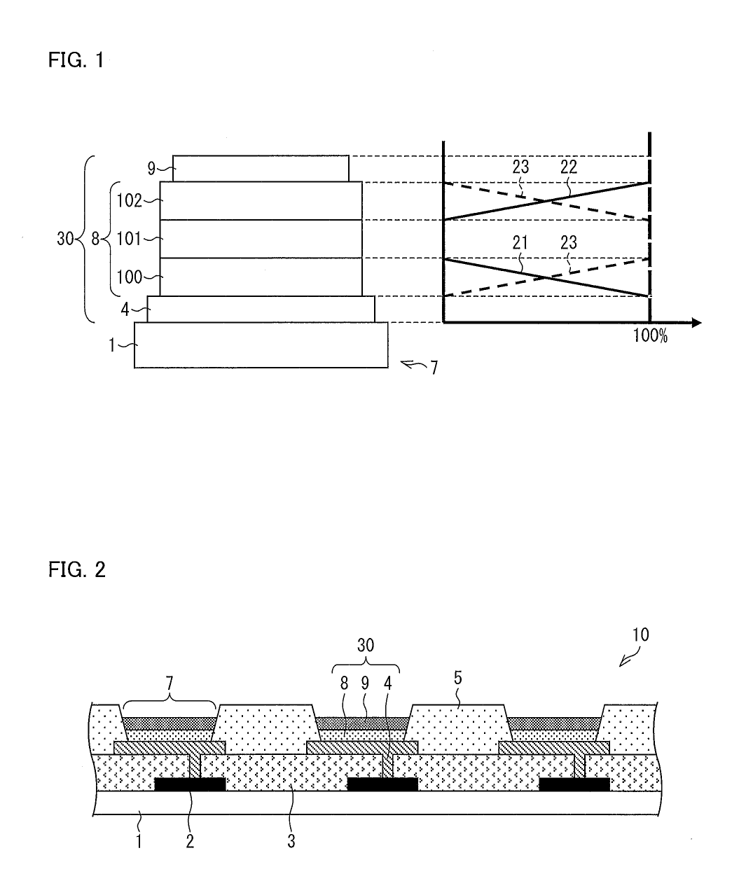

As early described, according to the present embodiment, the anode 4, the organic EL layer 8, and the cathode 9 are characterized in that the anode 4, the organic EL layer 8, and the cathode 9 constitute a single layer containing a positive and negative charge transporting material. The following description will discuss, with reference to FIG. 1, details of configurations of the anode 4, the organic EL layer 8, and the cathode 9. FIG. 1 is a view illustrating a cross-section of the organic EL element 7 and showing a concentration of each of materials constituting the organic EL element 7.

As illustrated in FIG. 1, the organic EL element 7 is constituted by the insulating substrate 1 and a single layer which is provided on the insulating substrate 1. The single layer includes the anode 4, the organic EL layer 8, and the cathode 9. Note that the TFT 2 and the interlayer insulating film 3 are omitted in FIG. 1, for convenience. The organic EL layer 8 has a hole transport region 100 (carrier transport region), a light-emitting region 101, and an electron transport region 102 (carrier transport region). The hole transport region 100 is located on an anode 4 side and the electron transport region 102 is located on a cathode 9 side. The light-emitting region 101 is located between the hole transport region 100 and the electron transport region 102.

In the anode 4 of the organic EL element 7, an acceptor is added to the positive and negative charge transporting material so as to have a concentration of 100% by weight. The acceptor is added to the positive and negative charge transporting material so that the concentration of the acceptor becomes lower toward the light-emitting region 101. That is, the material of the anode 4 is added, as the acceptor, to the organic EL layer 8. The hole transport region 100 is configured so that the acceptor has a concentration gradient in which the concentration 21 of the acceptor becomes continuously lower.

As illustrated in FIG. 1, the concentration 21 of the acceptor in the anode 4 is 100% by weight. In the hole transport region 100, the concentration 21 of the acceptor becomes continuously lower from the anode 4 toward the cathode 9, i.e., from 100% by weight at the anode 4 to 0% by weight at the light-emitting region 101. Accordingly, the concentration 23 of the positive and negative charge transporting material continuously increases from 0% by weight at the anode 4 to 100% by weight at the light-emitting region 101.

An organic light-emitting material is added to the light-emitting region 101 between the hole transport region 100 and the electron transport region 102. It is preferable that the organic light-emitting material be added to the positive and negative charge transporting material so that the concentration of the organic light-emitting material has preferably a concentration of about 1% by weight to 20% by weight, more preferably about 6% by weight.

Note that it is more preferable that the organic light-emitting material has a concentration gradient in which the concentration of the organic light-emitting material becomes continuously higher, in the light emitting region 101, (i) from an end surface on a hole transport region 100 side toward a center of the light-emitting region 101 and (ii) from an end surface on an electron transport region 102 side toward the center of the light-emitting region 101. Also note that the organic EL layer 8 can have a region, containing neither the acceptor nor the organic light-emitting material, between the hole transport region 100 and the light-emitting region 101. This makes it possible to prevent an energy transfer to the acceptor from an exciton generated in the organic light-emitting material. As such, it is possible to prevent the exciton from being deactivated. Likewise, the organic EL layer 8 can have a region, containing neither the donor nor the organic light-emitting material, between the electron transport region 102 and the light-emitting region 101. This makes it possible to prevent an energy transfer to the donor from an exciton generated in the organic light-emitting material. As such, it is possible to prevent the exciton from being deactivated.

In the organic EL element 7, the cathode 9 is made from a donor, which is added to the positive and negative charge transporting material so as to have a concentration of 100% by weight. The donor is added to the positive and negative charge transporting material so that a concentration 22 of the donor becomes continuously lower from 100% by weight at the cathode toward the light-emitting region 101. That is, the material of the cathode 9 is added, as the donor, to the organic EL layer 8. The electron transport region 102 is configured so that the donor has a concentration gradient in which the concentration 22 of the donor becomes continuously lower.

As illustrated in FIG. 1, the concentration 22 of the donor in the cathode 9 is 100% by weight. In the electron transport region 102, the concentration 22 of the donor becomes continuously lower from the cathode 9 toward the anode 4, i.e., from 100% by weight at the cathode 9 to 0% by weight at the light-emitting region 101. Accordingly, the concentration 23 of the positive and negative charge transporting material continuously increases from 0% by weight at the cathode 9 to 100% by weight at the light-emitting region 101.

According to the configuration, the anode 4 itself is constituted by an acceptor material, and the acceptor is added to the positive and negative charge transporting material so that the concentration of the acceptor becomes lower toward the light-emitting region 101. As such, in a boundary region between the anode 4 and the hole transport region 100, a work function level of the anode 4 substantially matches a Highest Occupied Molecular Orbital (HOMO) on which a hole propagates through the acceptor. This causes no energy barrier to be generated in the boundary region between the anode 4 and the hole transport region 100 and, ultimately, allows a hole to propagate efficiently from the anode 4 to the hole transport region 100. In a boundary region between the light-emitting region 101 and the hole transport region 100, (i) a concentration of the organic light-emitting material in the light-emitting region 101 is low and (ii) a concentration of the positive and negative charge transporting material in the hole transport region 100 is 100% by weight. As such, a HOMO of the positive and negative charge transporting material in the region, to which the acceptor is added, substantially matches a HOMO on which a hole propagates through the acceptor. This allows a hole to propagate efficiently from the hole transport region 100 to the light-emitting region 101.

Similarly, according to the configuration, the cathode 9 itself is constituted by a donor material, and the donor is added to the positive and negative charge transporting material so that the concentration of the donor becomes lower toward the light-emitting region 101. As such, in a boundary region between the cathode 9 and the electron transport region 102, a work function level of the cathode 9 substantially matches a Lowest Occupied Molecular Orbital (LOMO) on which an electron propagates through the donor. This causes no energy barrier to be generated in the boundary region between the cathode 9 and the electron transport region 102 and, ultimately, allows an electron to propagate efficiently from the cathode 9 to the electron transport region 102. In a boundary region between the light-emitting region 101 and the electron transport region 102, (i) a concentration of the organic light-emitting material in the light-emitting region 101 is low and (ii) a concentration of the positive and negative charge transporting material in the electron transport region 102 is 100% by weight. As such, a LUMO of the positive and negative charge transporting material in the electron transport region substantially matches a LUMO on which an electron propagates through the donor. This allows an electron to propagate efficiently from the electron transport region 101 to the light-emitting region 102.

As described above, in the organic EL element 7 in accordance with the present embodiment, no energy barrier is generated between (a) the organic EL layer 8 and (b) the respective electrodes. This allows a hole and an electron to be injected and transported efficiently and, ultimately, allows a driving voltage of the organic EL element 7 to be lowered. Further, the anode 4, organic EL layer 8, and the cathode 9 constitute a single layer in the organic EL element 7. This allows the organic EL element 7 to have a simple layer structure and, ultimately, allows a significant reduction in cost for fabricating the organic EL element 7.

Note that the present embodiment employs a configuration in which the concentration gradient of the acceptor and the concentration gradient of the donor are both linear. The present embodiment is not limited to this, provided that the concentration gradients are continuous. For example, the concentration gradients can be exponential.

### General Configuration of Anode 4

The following description will discuss the anode 4 in detail. The anode 4 is patterned into an island shape on the insulating substrate 1 (on the interlayer insulating film 3) and is electrically connected with the TFT 2 via the contact hole formed in the interlayer insulating film 3. The anode 4 has a function of injecting a hole into the organic EL layer 8. As early described, the anode 4 is made from an acceptor, which is added to the positive and negative charge transporting material so as to have a concentration of 100% by weight. As such, it is necessary that the acceptor employed in the present embodiment be a material with conductivity.

Examples of materials (acceptor) constituting the anode 4 encompass (i) electroconductive oxide such as zinc oxide (ZnO), oxide ruthenium (RuO₂), oxide molybdenum (MoO₃), tin oxide (SnO₂), and titanium oxide (TiO₂) and (ii) inorganic materials such as gold (Au), nickel (Ni), platinum (Pt), tungsten (W), and iridium (Ir).

### General Configuration of Cathode 9

The cathode 9 will be described below. The cathode 9 is provided so as to cover the organic EL layer 8 and the edge cover 5. The cathode 9 has a function of injecting an electron into the organic EL layer 8. As early described, the cathode 9 is made from a donor which is added to the positive and negative charge transporting material so as to have a concentration of 100% by weight. As such, it is necessary that the donor employed in the present embodiment have conductivity.

Examples of a material (donor) of the cathode 9 encompass inorganic materials such as an alkaline metal, an alkaline earth metal, a rare earth device, aluminum (Al), silver (Ag), copper (Cu), indium (In), and cesium (Cs).

### General Configuration of Organic EL Layer 8

The organic EL layer 8 will be described below. Each of the regions that the organic EL layer 8 has contains a positive and negative charge transporting material. A low-molecular material or a high-molecular material can be employed as the positive and negative charge transporting material. Examples of the low-molecular material include: benzofuran derivatives such as bis(carbazolyl)benzodifuran (CZBDF); cyclopentadiene derivatives; tetraphenylbutadiene derivatives; triphenylamine derivatives; oxadiazole derivatives; basophenanthroline derivatives; pyrazoloquinoline derivatives; styrylbenzene derivatives; styrylarylene derivatives; aminostyryl derivatives; silole derivatives; thiophene cyclic compounds; pyridine cyclic compounds; perynone derivatives; perylene derivatives; oligothiophene derivatives; coumarin derivatives; rubrene derivatives; quinacridone derivatives; squarium derivatives; porphyrin derivatives; styryl-based pigments; tetracene derivatives; pyrazoline derivatives; trifumanylamine derivatives; anthracene derivatives; diphenylanthracene derivatives; pyrene derivatives; carbazole derivatives; oxadiazole dimers; pyrazoline dimers; aluminum quinolinol complexes; benzoquinolinol beryllium complexes; benzooxazole zinc complexes; benzothiazole zinc complexes; azomethyl zinc complexes; porphyrin complexes; europium complexes, iridium complexes; platinum complexes; metal complexes each having Al, zinc (Zn), beryllium (Be), Pt, Ir, terbium (Tb), europium (Eu), dysprosium (Dy), etc. as its central metal and having an oxadiazole structure, a thiadiazole structure, a phenylpyridine structure, a phenylbenzoimidazole structure, a quinoline structure, or the like as its ligand; and the like.

Further, examples of the polymeric material include poly(oxadiazole) (Poly-OXZ), polystyrene derivatives (PSS), polyaniline-camphorsulfonic acid (PANI-CSA), poly(triphenylamine-oxadiazole) derivatives (Poly-TPD-OXD), and poly(carbazole-triazole) derivatives (Poly-Cz-TAZ).

In view of high-efficiency emission, it is preferable that the positive and negative charge transporting material have a singlet excitation level (S₁) that is higher in excitation level than the triplet excitation level (T₁) of the phosphorescent light-emitting material. That is, it is more preferable that the following relationship be maintained: S₁>T₁. This allows excitation energy to be contained in a phosphorescent material. Therefore, it is preferable that a carbazole group, a triazole group, or a benzofuran group, which are high in excitation level and hole mobility, is employed as the positive and negative charge transporting material.

The organic light-emitting material is added to the light-emitting region 101 in the organic EL layer 8. A publicly known organic light-emitting material for use in an organic EL element can be employed as the organic light-emitting material. Examples of the organic light-emitting material include (i) fluorescent materials such as styryl derivatives, perylene, iridium complexes, coumarin derivatives, Lumogen F Red, dicyanomethylnepyran, phenoxazone, and porphyrin derivatives and (ii) phosphorescent light-emitting organic metal complexes such as bis[(4,6-difluorophenyl)-pyridinato-N,C2′]picolinate iridium (III) (FIrpic), tris(2-phenylpyridyl)iridium (III) (Ir(ppy)₃), tris(1-phenylisoquinoline)iridium (III) (Ir(piq)3), and tris(biphenylquinoxalinato)iridium (III) (Q3Ir). In view of a drastic reduction in power consumption, it is preferable that the organic light-emitting material be a phosphorescent light-emitting material.

### General Configuration of Edge Cover 5

The edge cover 5 is provided between the respective organic EL elements 7. Note that the edge cover 5 is provided so that the edge cover 5 partially covers a peripheral part of the anode 4, which has been patterned. A region, on the anode 4, where the edge cover 5 is not provided, serves as an organic EL element 7. Since the edge cover 5 is provided so as to partially cover the peripheral portion of the anode 4, it is possible to prevent the anode 4 and the cathode 9 from being short-circuited. Such short-circuiting will be caused by (i) a reduction in thickness of the organic EL layer 8 in the peripheral part and/or (ii) electric field concentration.

Examples of materials of the edge cover 5 encompass (a) inorganic materials such as silicon oxide and silicon nitride, (b) organic resin materials such as an acrylic resin, a polyimide resin, photosensitive sol-gel materials, and a Novolac resin. Examples of the acrylic resin encompass Optomer® series (product of JSR Corporation). Examples of the polyimide resin encompass Photoneece™ series (product of Toray Co., Ltd.).

### Method for Fabricating Organic EL Display Device 10

The following description will discuss a method for fabricating the organic EL display device 10, with a concrete example. Note, however, that the method for fabricating the organic EL display device 10 in accordance with the present embodiment is not limited to such an example.

Initially, the plurality of TFTs 2 for driving an organic EL element are formed on an insulating substrate 1. The plurality of TFTs 2 can be formed by a conventionally known method such as (i) a method for carrying out ion-doping in which an impurity is added to an amorphous silicon film which has been formed by plasma-excited chemical vapor deposition (PECVD) and (ii) a method in which amorphous silicon is formed by low-pressure chemical vapor deposition (LPCVD) using a silane (SiH₄) gas, the amorphous silicon is crystallized by a solid-phase deposition to obtain polysilicon, and ion-doping is carried out by use of ion implantation.

Next, the interlayer insulating film 3 is formed to smooth an uneven surface defined by the plurality of TFTs 2 provided on the insulating substrate 1. The following description will discuss an example in which the interlayer insulating film 3 is made from an acrylic resin. Initially, a photosensitive positive acrylic resin material is applied by spin coating on the insulating substrate 1, on which the plurality of TFTs 2 have been formed. The insulating substrate 1 over which the photosensitive positive acrylic resin material have been applied is pre-baked at 80° C. for 3 minutes, so that an acrylic film (interlayer insulating film 3) is obtained. Subsequently, a part of the acrylic film, in which part a terminal of each of the plurality of TFTs 2 is to be electrically connected with the anode 4, is removed by photolithography, and the insulating substrate is post-baked at 220° C. for one (1) hour. Thus obtained is the interlayer insulating film 3 with contact holes. Note that the interlayer insulating film 3 preferably has a film thickness of about 1 pm.

Next, the anode 4 is formed. The following description will discuss an example in which the anode 4 is a RuO₂ electrode. A RuO₂ thin-film is patterned, by an evaporation method using RuO₂, on the insulating substrate 1, on which the interlayer insulating film 3 has been formed. Thus obtained is the RuO₂ electrode (anode 4). Note that the anode 4 preferably has a film thickness of about 350 nm. According to the present embodiment, the anode 4 is formed by an evaporation method. Note, however, that the method for forming the anode 4 is not to be limited to this. The anode 4 can be formed by (a) another dry process such as radio-frequency magnetron sputtering or (b) a wet process such as inkjet printing.

Subsequently, the edge cover 5 is formed. The following description will discuss an example in which the edge cover 5 is made from a polyimide resin. First, a photosensitive positive polyimide resin material is applied, by spin coating, on the insulating substrate 1, on which the anode 4 has been formed. The insulating substrate 1, over which the photosensitive positive polyimide resin material has been applied, is pre-baked at 100° C. for 3 minutes, so that a polyimide film (edge cover 5) is obtained. Subsequently, a part of the polyimide film, on the anode 4, is removed by photolithography, and the insulating substrate 1 is post-baked at 220° C. for one (1) hour. Thus obtained is the edge cover 5. Note that the edge cover 5 preferably has a film thickness of about 1.5 pm to 2.0 pm.

Next, the organic EL layer 8 is formed. Initially, the hole transport region 100 is formed. The following description will discuss an example in which the acceptor material is RuO₂ and the positive and negative charge transporting material is bis(carbazolin)benzodifuran (CZBDF). In the example, RuO₂ and CZBDF are applied onto the anode 4 by co-evaporation so as to have a thickness of 40 nm. The hole transport region 100 is thus formed. In so doing, RuO₂ is added to CZBDF so as to have (i) a concentration of 100% by weight on a first surface where the hole transport region 100 is in contact with the anode 4 and (ii) a concentration of 0% by weight on a second surface of the hole transport region 100, the first and second surfaces facing each other. To put it differently, the acceptor material and CZBDF are subjected to the co-evaporation so that the concentration of RuO₂ becomes linearly lower from the first surface toward the second surface, i.e., from 100% by weight toward 0% by weight.

Thus, according to the present invention, it is possible that, subsequent to formation of the anode 4, the hole transport region 100 is formed in the organic EL layer 8 by the same evaporation process as that employed in the formation of the anode 4. That is, the anode 4 and the organic EL layer 8 are formed as a single layer, not as different layers. This allows a further reduction in cost for fabricating the organic EL element 7.

Next, the light-emitting region 101 is formed on the hole transport region 100. The following description will discuss an example in which tris(2-phenylpyridyl)iridium (III) (Ir(ppy)₃) is employed as the light-emitting material. First, Ir(ppy)₃ and CZBDF (positive and negative charge transporting material) are subjected to the co-evaporation on the hole transport region 100. In so doing, Ir(ppy)₃ is added to CZBDF so as to have a concentration of 6% by weight. Thus obtained is the light-emitting region 101. Note that the region, to which the light-emitting material is added, preferably has a film thickness of about 20 nm.

Subsequently, the electron transport region 102 is formed on the light-emitting region 101. The following description will discuss an example in which the donor material is Al. First, Al and CZBDF (positive and negative charge transporting material) are applied onto the light-emitting region 101 by co-evaporation so as to have a thickness of 40 nm. The electron transport region 102 is thus formed. In so doing, Al is added to CZBDF so as to have (i) a concentration of 0% by weight on a third surface where the electron transport region 102 is in contact with the light-emitting region 101 and (ii) a concentration of 100% by weight on a fourth surface of the electron transport region 102, the third and fourth surfaces facing each other. To put it differently, Al and CZBDF are subjected to the co-evaporation so that the concentration of Al becomes linearly higher from the third surface toward the fourth surface, i.e., from 0% by weight toward 100% by weight. Thus obtained is the electron transport region 102.

Next, the cathode 9 is formed on the electron transport region 102. The following description will discuss an example in which the cathode 9 is an Al electrode. An Al electrode (cathode 9) is deposited on the electron transport region 102 at a deposition rate of about 2 nm/sec. Thus obtained is the cathode 9. Note that the cathode 9 preferably has a film thickness of about 1,000 nm.

Thus, according to the present embodiment, it is possible that, subsequent to formation of the electron transport region 102, the cathode 9 is formed by the same evaporation process as that used in the formation of the electron transport region 102. That is, the organic EL layer 8 and the cathode 9 are formed as a single layer, not as different layers. This allows a further reduction in cost for fabricating the organic EL element 7.

Finally, the insulating substrate 1 is sealed. A sealing substrate is combined, from above the cathode 9, with the insulating substrate 1, via an ultraviolet ray curing resin. Subsequently, the ultraviolet ray curing resin is cured by being irradiated with UV light of 6,000 mJ emitted from a UV lamp, so that the insulating substrate 1 is sealed with the sealing substrate. Thus obtained is the organic EL display device 10.

Thus, according to the present embodiment, it is possible to provide the organic EL display device 10 including displaying means in which the organic EL element 7 is provided on the thin-film transistor substrate.

### Second Embodiment

### General Configuration of Organic El Display Device 10a

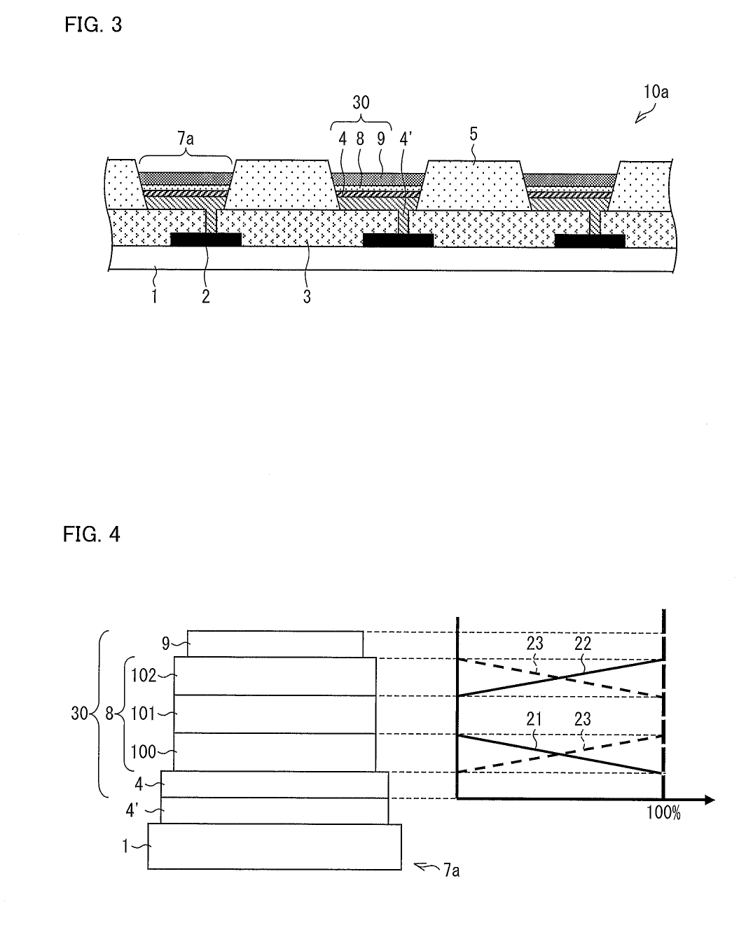

The organic EL display device 10a in accordance with the present embodiment has the same configuration as that of the organic EL display device 10 in accordance with the First Embodiment, except that electrodes 4′ are provided in addition to anodes 4. The following description will discuss, with reference to FIGS. 3 and 4, a general configuration of the organic EL display device 10a in accordance with the present embodiment. FIG. 3 is a cross-sectional view illustrating the organic EL display device 10a in accordance with the present embodiment. FIG. 4 is a view illustrating a cross-section of an organic EL element 7a and showing a concentration of each of materials constituting the organic EL element 7a.

As illustrated in FIG. 3, the organic EL display device 10a includes an insulating substrate 1, a plurality of TFTs 2, interlayer insulating films 3, the transparent electrodes 4′, the anodes 4, edge covers 5, organic EL layers 8, and cathodes 9. On the insulating substrate 1, the plurality of TFTs 2 are formed at predetermined intervals. Each of the interlayer insulating films 3, which have been smoothed, is provided on corresponding two of the plurality of TFTs 2. A terminal of each of the plurality of TFTs 2 is electrically connected with a corresponding one of the transparent electrodes 4′ via a corresponding contact hole provided in the interlayer insulating film 3. Each of the anodes 4 is provided on a corresponding one of the transparent electrodes 4′ so as to face a corresponding one of the plurality of TFTs 2. Each of the organic EL layers 8 and a corresponding one of the cathodes 9 are provided on a corresponding one of the anodes 4 in this order. The insulating substrate 1, a transparent electrode 4′, an anode 4, an organic EL layer 8, and a cathode 9 constitute an organic EL element 7a. An edge cover 5 is provided between respective adjacent organic EL elements 7a.

Like the First Embodiment, according to the present embodiment, each of the anodes 4, a corresponding one of the organic EL layers 8, and a corresponding one of the cathodes 9 constitute a positive and negative charge transporting layer 30 (a single layer) containing a positive and negative charge transporting material. As illustrated in FIG. 4, the organic EL element 7a is obtained by forming, on the transparent electrode 4′ of the insulating substrate 1, a single layer having the anode 4, the organic EL layer 8, and the cathode 9. Note that the TFT 2 and the interlayer insulating film 3 are omitted in FIG. 4, for convenience. Like the First Embodiment, an acceptor material and a donor material are added to the organic EL layer 8 so that the acceptor material and the donor material have their respective concentration gradients. Note that examples of the transparent electrode 4′ encompass an electrode made from a conductive material with optical transparency, such as indium tin oxide (ITO) and indium zinc oxide (IZO).

As early described, the organic EL display device 10a in accordance with the present embodiment has the transparent electrode 4′ in addition to the anode 4. As is clear from the First Embodiment, in a case where the anode 4 is made from RuO₂, the anode 4 has a film thickness of about 350 nm, which is not thin. Accordingly, a transmittance of the anode 4 for visible light becomes about 10%, which is not large. Therefore, it becomes sometimes difficult for light emitted from the organic EL element 7a to be emitted from an insulating substrate 1 side. In view of the circumstances, the present embodiment employs, as an electrode, the transparent electrode 4′ having a high transmittance for visible light. For example, in a case where the anode 4′ is an ITO electrode, the anode 4′ has a high transmittance for visible light, i.e., about 90%. In a case where (i) an ITO electrode with a film thickness of about 120 nm is formed as the transparent electrode 4′ and (ii) a RuO₂ film of about 30 nm in thickness is laminated as the anode 4 on the transparent electrode 4′, a transmittance for visible light becomes 60%. The transmittance for visible light becomes three times as high as that obtained in a case like the First Embodiment in which the anode 4 is made from RuO₂ alone. It thus becomes possible to improve an efficiency of light, emitted from the organic EL element 7a, being emitted from the insulating substrate 1 side. In addition, an efficient injection and transportation of a hole and an electron is maintained. This allows low voltage driving of the organic EL display device 10a to be maintained.

### Method for Fabricating Organic EL Display Device 10a

The following description will discuss a method for fabricating the organic EL display device 10a.

The organic EL display device 10a is fabricated by the same method as the method for fabricating the organic EL display device 10 in accordance with the First Embodiment, except that the transparent electrode 4′ is formed in addition to the anode 4. The following description will therefore discuss only methods for forming the transparent electrode 4′ and the anode 4.

First, the transparent electrode 4′ is fabricated. The following description will discuss an example in which the transparent electrode 4′ is an ITO electrode. A thin-film of ITO is patterned on the interlayer insulating film 3, which has been formed on the insulating substrate 1, by radio-frequency magnetron sputtering, under the conditions where (i) ITO, to which 5% by weight of tin oxide is added, is employed as a target and (ii) Ar, into which oxygen (0₂) is introduced by 1%, is employed as a sputtering gas. Thus formed is the ITO electrode (transparent electrode 4′). Note that the transparent electrode 4′ preferably has a film thickness of about 120 nm. In the present embodiment, the transparent electrode 4′ is formed by sputtering. Note, however, that the transparent electrode 4′ can be formed by (i) another dry process such as vapor deposition, (ii) a wet process such as inkjet printing, or the like.

Next, the anode 4 is formed. The following description will discuss an example in which the anode 4 is a RuO₂ electrode. A thin-film of RuO₂ is patterned, by an evaporation method using RuO₂, on the interlayer insulating film 3 which has been formed on the insulating substrate 1. Thus formed is the RuO₂ electrode (anode 4). Note that the anode 4 preferably has a film thickness of about 30 nm. In the present embodiment, the anode 4 is formed by an evaporation method. Note, however, that the present embodiment is not limited to this. For example, the anode 4 can be formed by (a) another dry process such as radio-frequency magnetron sputtering, (b) a wet process such as inkjet printing, or the like. Subsequent fabricating processes are the same as those of the First Embodiment and descriptions on such fabricating processes will therefore be omitted.

In the present embodiment, the transparent electrode 4′ is provided so as to be in contact with a first surface of the anode, which first surface is on the opposite side of a second surface of the anode, which second surface is in contact with the organic layer 8. Note, however, that the present invention is not limited to this. The transparent electrode 4′ can be provided on a third surface of the cathode, which third surface is on the opposite side of a fourth surface of the cathode 9, which fourth surface is in contact with the organic layer 8. That is, it is only necessary that the transparent electrode 4′ is provided on at least one of the anode side and the cathode side, preferably provided as an electrode on a side through which light is taken out.

### Third Embodiment

### General configuration of Organic EL Display Device 10b

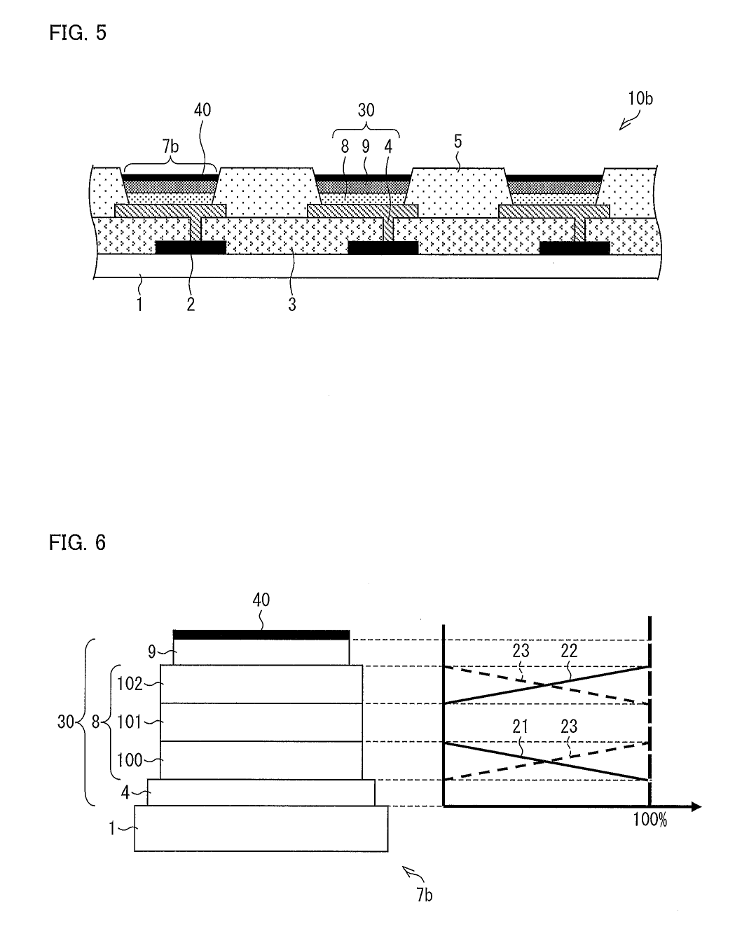

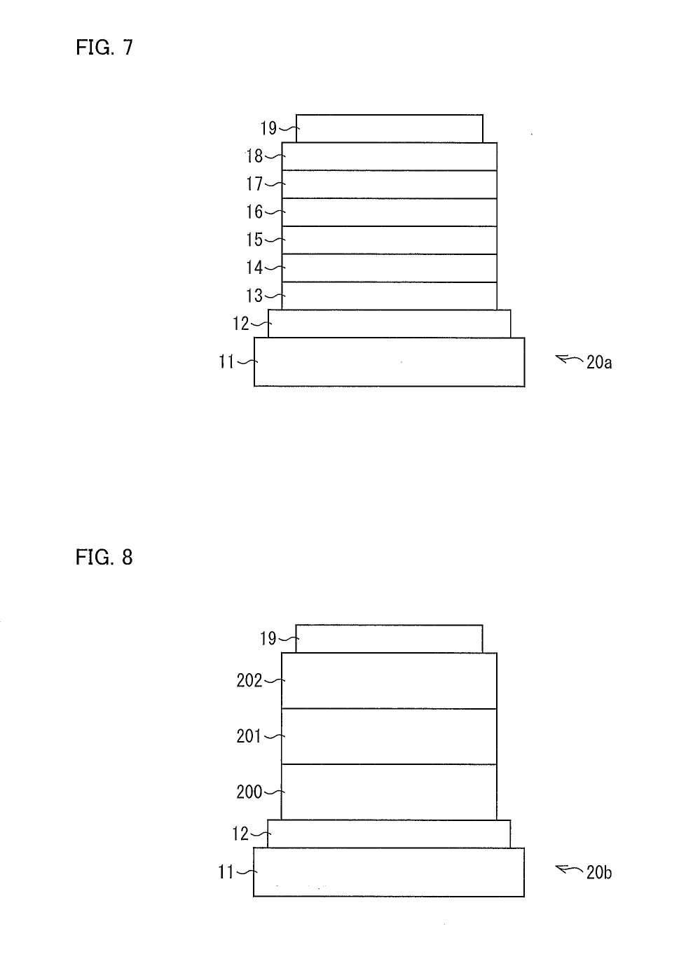

The organic EL display device 10b in accordance with the present embodiment has the same configuration as that of the organic EL display device 10 in accordance with the First Embodiment, except that inorganic films 40 are further provided on respective cathodes 9. The following description will discuss, with reference to FIGS. 5 and 6, a general configuration of the organic EL display device 10b in accordance with the present embodiment. FIG. 5 is a cross-sectional view illustrating the organic EL display device 10b in accordance with the present embodiment. FIG. 6 is a view illustrating a cross-section of an organic EL element 7b and showing a concentration of each of materials constituting the organic EL element 7b.

As illustrated in FIG. 5, the organic EL display device 10b includes an insulating substrate 1, a plurality of TFTs 2, interlayer insulating films 3, anodes 4, edges cover 5, organic EL layers 8, the cathodes 9, and the inorganic films 40. On the insulating substrate 1, the plurality of TFTs 2 are formed at predetermined intervals. Each of the interlayer insulating films 3, which have been smoothed, is provided on corresponding two of the plurality of TFTs 2. A terminal of each of the plurality of TFTs 2 is electrically connected with a corresponding one of the anodes 4 via a corresponding contact hole provided in the interlayer insulating film 3. Each of the organic EL layers 8 and a corresponding one of the cathodes 9 are provided on a corresponding one of the anodes 4. Each of the inorganic films 40 is provided on a corresponding one of the cathodes 9. The insulating substrate 1, the anode 4, the organic EL layer 8, the cathode 9, and the inorganic film 40 constitute the organic EL element 7b. An edge cover 5 is provided between respective adjacent organic EL elements 7b.

Accordance to the present embodiment, like the First Embodiment, the anode 4, the organic EL layer 8, and the cathode 9 constitute a positive and negative charge transporting layer 30 (a single layer) containing a positive and negative charge transporting material. As illustrated in FIG. 6, the organic EL element 7b is constituted by the insulating substrate 1 and the single layer which is provided on the insulating substrate 1. The single layer includes the anode 4, the organic EL layer 8, the cathode 9, and the inorganic film 40. Note that the TFT 2 and the interlayer insulating film 3 are omitted in FIG. 6, for convenience. Like the First Embodiment, an acceptor material and a donor material are added to the organic EL layer 8 so that the acceptor material and the donor material have their respective concentration gradients. Examples of materials of the inorganic film 40 encompass SiO₂, SiON, and SiN. Note that the inorganic film 40 in accordance with the present embodiment is not limited to these materials.

As early described, in the organic EL display device 10b in accordance with the present embodiment, the inorganic film 40 is provided on the cathode 9. In a case where a material (e.g., Cs) having a work function lower than that of Al is employed, in place of Al, as the cathode 9 in the First Embodiment, the cathode 9 easily reacts with oxygen or moisture in the atmosphere. This prevents the cathode 9 from maintaining its characteristics to serve as a cathode and, ultimately, causes deterioration in light-emission characteristics such as an increase in driving voltage of, a decrease in luminance of, and a shortening of lifespan of the organic EL element.

In view of the circumstances, according to the present embodiment, the inorganic film 40 is provided on the cathode 9 so as to block the cathode 9 from oxygen and moisture in the atmosphere. The provision of the inorganic film 40 does not impair the efficiency of the injection and the transportation of a hole and an electron. It is therefore possible to maintain the low voltage driving of the organic EL display device 10b.

### Method for Fabricating Organic EL Display Device 10b

The following description will discuss a method for fabricating the organic EL display device 10b.

In the method for fabricating the organic EL display device 10b, the processes similar to those of the method for fabricating the organic EL display device 10 in accordance with the First Embodiment are carried out, until the step of forming the edge cover 5. The following description will therefore discuss only the step of forming the organic EL layer 8 and subsequent steps in the method for fabricating the organic EL display device 10b.

First, the organic EL layer 8 is formed. The hole transport region 100 is initially formed in a manner similar to the First Embodiment. Next, the light-emitting region 101 is formed on the hole transport region 100 in a manner similar to the First Embodiment.

Subsequently, the electron transport region 102 is formed on the light-emitting region 101. The following description will discuss an example in which the donor material is Cs. In the example, Cs and CZBDF (positive and negative charge transporting material) are applied onto the light-emitting region 101 by co-evaporation so as to have a thickness of 40 nm. The electron transport region 102 is thus formed. In so doing, Cs is added to CZBDF so as to have (i) a concentration of 0% by weight on a fifth surface where the electron transport region 102 is in contact with the light-emitting region 101 and (ii) a concentration of 100% by weight on a sixth surface of the electron transport region 102, the fifth and sixth surfaces facing each other. To put it differently, Cs and CZBDF are subjected to the co-evaporation so that the concentration of Cs becomes linearly higher from the fifth surface toward the sixth surface, i.e., from 0% by weight toward 100% by weight. Thus obtained is the electron transport region 102.

Next, the cathode 9 is formed on the electron transport region 102. The following description will discuss an example in which the cathode 9 is a Cs electrode. A Cs electrode (cathode 9) is deposited on the electron transport region 102 at a deposition rate of about 2 nm/sec. Thus obtained is the cathode 9. Note that the cathode 9 preferably has a film thickness of about 1,000 nm.

Next, the inorganic film 40 is formed on the cathode 9. The following description will discuss an example in which the inorganic film 40 is made from SiO₂. In the example, a 1-μm-thick SiO₂ film is formed on the cathode 9 by sputtering using a shadow mask. Finally, the insulating substrate 1 is sealed in a manner similar to the First Embodiment. Thus obtained is the organic EL display device 10b.

In the present embodiment, the cathode 9 is made from Cs having a low work function. Note, however, that the inorganic film 40 can be formed on the cathode 9 irrespective of whether the work function is high or low.

The present invention is not limited to the above-described embodiments but allows various modifications within the scope of the claims. In other words, any embodiment derived from a combination of two or more technical means appropriately modified within the scope of the claims will also be included in the technical scope of the present invention.

For example, in each of the three embodiments described above, the anode 4 is constituted by the acceptor and the cathode 9 is constituted by the donor. Note, however, that it is only necessary in the present invention that at least one of the pair of electrodes (the anode 4 and the cathode 9) be constituted by a same material as that for the dopant that enhances transportation of a carrier to be injected by the electrode into the organic EL layer 8. This allows at least one of two types of carriers (hole and electron) to be efficiently injected and transported and, ultimately, allows the driving voltage of the organic EL element 7 to be lowered. Further, it also becomes possible to form at least one of the anode 4 and the cathode 9 so that the at least one of the anode 4 and the cathode 9 and the organic EL layer 8 constitute a single layer, not different layers. This allows the organic EL element 7 to have a simple layer structure and, ultimately, allows a significant reduction in cost for fabricating the organic EL element 7.

In Embodiments 2 and 3, the organic EL layer 8 contains CZBDF as the positive and negative charge transporting material. That is, the organic EL layer 8 has a homojunction structure. This simplifies the entire layer structure of the organic EL element 7. Note, however, that the present invention can employ a configuration in which the organic EL layer 8 has a heterojunction structure, in which a plurality of different hosts are included as different layers.

### Overview of Embodiment

As described above, the organic electroluminescent element in accordance with the present invention, it is preferable that one of the pair of electrodes be an anode constituted by an acceptor serving as the dopant, the other of the pair of electrodes be a cathode constituted by a donor serving as the dopant, the organic layer include (i) a hole transport region which serves as the carrier transport region and is located closer to the anode than the light-emitting region is and (ii) an electron transport region which serves as the carrier transport region and is located closer to the cathode than the light-emitting region is, the acceptor being added to the hole transport region so that the acceptor has a concentration gradient in which a concentration of the acceptor becomes lower from the anode toward the light-emitting region, the donor being added to the electron transport region so that the donor has a concentration in which a concentration of the donor becomes lower from the cathode toward the light-emitting region.

According to the configuration, both holes and electrons can be efficiently injected and transported. This allows (i) the organic EL element to have a further improvement in luminous efficiency and in lifespan and (ii) the driving voltage to be further lowered. Moreover, the configuration allows the anode and the cathode to be formed so that the anode, the cathode, and the organic layer constitute a single layer, not different layers. This allows the organic EL element to have a simpler layer structure and, ultimately, allows a further reduction in cost for fabricating the organic EL element.

In the organic electroluminescent element in accordance with the present invention, it is preferable that the organic light-emitting material be added to the light-emitting region so as to have a concentration gradient in which a concentration of the organic light-emitting material becomes higher, in the light-emitting region, from an end surface(s) on a carrier transport region side(s) toward a center of the light-emitting region.

According to the configuration, the concentration of the organic light-emitting material is low in a boundary region between the light-emitting region and the carrier transport region. This allows a carrier having propagated through the dopant to propagate efficiently in the boundary region and, ultimately, allows the carrier to propagate completely to the light-emitting region.

In the organic electroluminescent element in accordance with the present invention, it is preferable that the organic layer further include at least one region to which neither the dopant nor the organic light-emitting material is added, the at least one region being sandwiched between the light-emitting region and the carrier transport region.

According to the configuration, the organic light-emitting material and the dopant (acceptor, carrier) are never in direct contact with each other. This makes it possible to prevent an energy transfer to the dopant from an exciton generated in the organic light-emitting material. It thus becomes possible to achieve efficiently high luminous efficiency.

In the organic electroluminescent element in accordance with the present invention, it is preferable that the concentration of the dopant exponentially changes in the concentration gradient.

According to the configuration, the carrier can propagate efficiently to the light-emitting region. This makes it possible to improve luminous efficiency.

It is preferable that the organic electroluminescent element in accordance with the present invention further include: a transparent electrode provided on a first surface of at least one of the pair of electrodes, the first surface being on an opposite side of a second surface of the at least one of the pair of electrodes, the second surface being in contact with the organic layer.

According to the configuration, the provision of the transparent electrode other than the electrodes (anode, cathode) allows an improvement in transmittance of light through the electrodes. This makes it possible to take out more efficiently light emitted from the organic EL element.

In the organic electroluminescent element in accordance with the present invention, it is preferable that the organic layer have a structure in which the dopant and the organic light-emitting material are added to a positive and negative charge transporting material.

According to the configuration, it is possible to provide the organic layer as a single layer. This allows a more simplified layer structure.

The embodiments and concrete examples of implementation discussed in the foregoing detailed explanation serve solely to illustrate the technical details of the present invention, which should not be narrowly interpreted within the limits of such embodiments and concrete examples, but rather may be applied in many variations within the spirit of the present invention, provided such variations do not exceed the scope of the patent claims set forth below.

### INDUSTRIAL APPLICABILITY

The present invention can be applied to various devices employing an organic EL element. The present invention can be applied to a display device such as a TV, and the like.

### REFERENCE SIGNS LIST

1: insulating substrate
2: thin-film transistor
3: interlayer insulating film
4: anode
4′: transparent electrode
5: edge cover
7, 7a, 20a, and 20b: organic electroluminescent element
8: organic electroluminescent layer
9: cathode
10 and 10a: organic electroluminescent display device
11: substrate
12: anode
13: hole injection layer
14: hole transport layer
15: light-emitting layer
16: hole blocking layer
17: electron transport layer
18: electron injection layer
19: cathode
30: positive and negative charge transporting layer
40: inorganic film
100: hole transport region
101: light-emitting region
102: electron transport region
200: acceptor region
201: light-emitting region
202: donor region

1. An organic electroluminescent element comprising:
a substrate;
a pair of electrodes; and
an organic layer, sandwiched between the pair of electrodes, which includes at least a light-emitting region to which an organic light-emitting material is added,
at least one of the pair of electrodes being constituted by a dopant,
the organic layer further including a carrier transport region to which the dopant is added so that the dopant has a concentration gradient in which a concentration of the dopant changes continuously from the at least one of the electrodes toward the light-emitting region.

2. The organic electroluminescent element as set forth in claim 1, wherein
one of the pair of electrodes is an anode constituted by an acceptor serving as the dopant,
the other of the pair of electrodes is a cathode constituted by a donor serving as the dopant,
the organic layer includes (i) a hole transport region which serves as the carrier transport region and is located closer to the anode than the light-emitting region is and (ii) an electron transport region which serves as the carrier transport region and is located closer to the cathode than the light-emitting region is,
the acceptor being added to the hole transport region so that the acceptor has a concentration gradient in which a concentration of the acceptor becomes lower from the anode toward the light-emitting region,
the donor being added to the electron transport region so that the donor has a concentration gradient in which a concentration of the donor becomes lower from the cathode toward the light-emitting region.

3. The organic electroluminescent element as set forth in claim 1, wherein the organic light-emitting material is added to the light-emitting region so as to have a concentration gradient in which a concentration of the organic light-emitting material becomes continuously higher, in the light-emitting region, from an end surface(s) on a carrier transport region side(s) toward a center of the light-emitting region.

4. The organic electroluminescent element as set forth in claim 1, wherein the organic layer further includes at least one region to which neither the dopant nor the organic light-emitting material is added, the at least one region being sandwiched between the light-emitting region and the carrier transport region.

5. The organic electroluminescent element as set forth in claim 1, wherein the concentration of the dopant exponentially decrease from the at least one of the electrodes toward the light-emitting region.

6. An organic electroluminescent element as set forth in claim 1, further comprising:
a transparent electrode provided on a first surface of at least one of the pair of electrodes, the first surface being on an opposite side of a second surface of the at least one of the pair of electrodes, the second surface being in contact with the organic layer.

7. The organic electroluminescent element as set forth in claim 1, wherein the organic layer has a structure in which the dopant and the organic light-emitting material are added to a positive and negative charge transporting material.

8. An organic electroluminescent display device comprising displaying means in which an organic electroluminescent element as set forth in claim 1 is provided on a thin-film transistor substrate.
